(19) United States
(12) Patent Application Publication
(10) Pub. No.: US 2026/0303109 A1
(43) Pub. Date: Oct. 1, 2026

(54) DIGITAL FOREGROUND CALIBRATION SYSTEM AND METHOD FOR SUCCESSIVE APPROXIMATION REGISTER ANALOG-TO-DIGITAL CONVERTER BASED ON RRAM

(71) Applicant: HUAZHONG UNIVERSITY OF SCIENCE AND TECHNOLOGY, Hubei (CN)

(72) Inventors: Xingsheng Wang, Hubei (CN); Juncheng Huang, Hubei (CN); Qingjie Wang, Hubei (CN); Fan Yang, Hubei (CN); Yifeng Xiong, Hubei (CN); Fang Cheng, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/449,356

(22) Filed: Jan. 14, 2026

(30) Foreign Application Priority Data
Mar. 26, 2025 (CN) 202510361236.6

(51) Int. Cl. H03M 1/10; G11C 13/00; H03M 1/46

(52) U.S. Cl. CPC H03M 1/1061; G11C 13/004; G11C 13/0069; H03M 1/462

(57) ABSTRACT

Disclosed are a digital foreground calibration system and method for a successive approximation register analog-to-digital converter based on RRAM. The system includes: a step voltage generating module, a status monitoring module, an information storage module, and a data processing module. The step voltage generating module is only effective in a calibration mode, and the data processing module is effective in an operation mode. The status detect module receives the output of the ADC to be calibrated and detects its mode. The information storage module uses RRAM-based storage array units, stores calibration codes generated by the step voltage generating module in the calibration mode, and in the operation mode continuously input data to the data processing module for accumulation and cutting to generate calibrated output codes.

### CROSS-REFERENCE TO RELATED APPLICATION

This application claims the priority benefit of China application serial no. 202510361236.6, filed on Mar. 26, 2025. The entirety of the above-mentioned patent application is hereby incorporated by reference herein and made a part of this specification.

### BACKGROUND

### Technical Field

The present disclosure belongs to the technical field related to integrated circuits, and more specifically, relates to a digital foreground calibration system and method for a successive approximation register analog-to-digital converter based on RRAM.

### Description of Related Art

In terms of a Successive Approximation Register Analog-to-Digital Converter (SAR ADC), a switching energy consumption of its capacitor array is a primary source of energy consumption. Reducing a unit capacitance area may significantly decrease this energy consumption. However, decreasing the unit capacitance area leads to an increase in a mismatch rate between unit capacitances, which may prevent the ADC from meeting the required linearity standards. Implementing foreground calibration for the SAR ADC may, to some extent, compensate for the errors caused by capacitor mismatch, thereby enhancing system linearity and reducing the linearity requirements concerning capacitor mismatch.

Current digital foreground calibration schemes for SAR ADCs lack non-volatile memory, resulting in the loss of stored data each time power is disconnected. Consequently, it is necessary for SAR ADCs to enter a calibration mode every time they are powered on before operation, significantly wasting time and energy.

Therefore, it is presently required to design a non-volatile, ultra-low-power foreground calibration scheme for the SAR ADC. This scheme aims to calibrate errors caused by capacitor mismatches in the ADC, enhance the linearity of the SAR ADC, relax the requirements for capacitor mismatch ratios, and improve the overall energy efficiency of the SAR ADC system.

### SUMMARY

In view of the defects of related technologies, the purpose of the present disclosure is to provide a digital foreground calibration system and method for a successive approximation register analog-to-digital converter based on RRAM, aiming to solve the problem that the existing digital foreground calibration schemes do not have non-volatility, resulting in the stored data being lost after each power-off, and having to enter a calibration mode before operation each time, which significantly wastes time and energy consumption.

To achieve the above purpose, in a first aspect, the present disclosure provides a digital foreground calibration system for the successive approximation register analog-to-digital converter based on RRAM, including: a step voltage generating module, a status monitoring module, an information storage module and a data processing module. The step voltage generating module is only effective in the calibration mode and is cut off in an operation mode. The data processing module is cut off in the calibration mode and is effective in the operation mode.

The step voltage generating module includes an N+M bit-width counter and a digital-to-analog converter with a resolution of N+M bits. An input terminal of the counter is connected with an external clock, an output terminal of the counter is connected with an input terminal of the digital-to-analog converter, and an output terminal of the digital-to-analog converter is connected with an input terminal of the successive approximation register analog-to-digital converter to be calibrated. The counter is provided to generate a continuously self-incrementing digital code, and the digital-to-analog converter is provided to convert the digital code into a continuously rising analog step voltage Vt for output to the successive approximation register analog-to-digital converter to be calibrated, wherein, M and N are both positive integers.

The status monitoring module includes a status detection logic unit and a selector. In the calibration mode, an input terminal of the status detection logic unit is connected with an output terminal of the successive approximation register analog-to-digital converter to be calibrated, an output terminal is connected with an input terminal of the selector, and an output terminal of the selector is connected with the information storage module. The status detection logic unit is provided to detect a mode of a digital output code of the successive approximation register analog-to-digital converter to be calibrated, and the selector is provided to respond to different control signals according to the mode of the digital output code. In the operation mode, an input terminal of the status monitoring logic unit is connected with the output terminal of the calibrated successive approximation register analog-to-digital converter. The status detection logic unit is provided to detect the mode of the digital output code of the calibrated successive approximation register analog-to-digital converter, and the selector is provided to respond to the different control signals according to the mode of the digital output code.

The information storage module includes an address control unit and an RRAM-based storage array unit. In the calibration mode, the storage array unit is connected with the counter, and is provided to store N (N+M)-bit digital calibration codes generated by the step voltage generating module. The address control unit is provided to select different columns in a storage array according to the control signal output by the status monitoring module, and write the digital calibration codes into the storage array. In the operation mode, the storage array unit is connected with the data processing module, and the address control unit is provided to select the different columns in the storage array according to the control signal output by the status monitoring module, and read the digital calibration codes from the storage array.

The data processing module includes an N+M-bit data accumulator and an N-bit data cutter. An input terminal of the data accumulator is connected with the information storage module, and an output terminal is connected with an input terminal of the data cutter. The data accumulator is provided to accumulate the selected N+M-bit digital calibration codes in the information storage module, and the data cutter is provided to cut data, only retaining the top N bits, serving as an output of the calibrated successive approximation register analog-to-digital converter.

Optionally, the counter receives an external clock signal, and at each rising edge of the clock signal, the output is self-incremented to generate a digital code with a bit-width of N+M bits.

The digital-to-analog converter periodically converts the digital output code of the counter into an analog voltage under the control of a system clock, obtaining the step voltage Vt, and output the step voltage Vt to the successive approximation register analog-to-digital converter. The step voltage Vt includes all scenarios of an N-bit digital output.

Optionally, in the calibration mode, the status monitoring module is provided to automatically detect the mode of the digital output code of the successive approximation register analog-to-digital converter to be calibrated, detecting whether its mode is only one bit being “1” while all remaining bits are “0”. If a detection result is true, then a position where “1” is located in the digital output code is detected, and the selector is provided to respond to the different control signals according to the detected position and output to the information storage module. If the detection result is false, then a current calibration cycle is directly skipped.

In the operation mode, the status monitoring module is provided to automatically monitor the mode of the digital output code of the calibrated successive approximation register analog-to-digital converter, detecting the number n of digital codes being “1” therein, and accordingly setting an operation cycle of this operation mode to n, and detecting a position where each “1” is located in the digital output code. The selector is provided to respond to the different control signals for each different “1” in the following n operation cycles.

Optionally, in the calibration mode, the address control unit in the information storage module is provided to receive the control signal responded by the status detection module, select the columns at different positions in the storage array, and store the digital output code corresponding to this cycle to the corresponding position as the digital calibration code.

In the operation mode, the address control unit in the information storage module is provided to receive the control signal responded by the status detection module, select the columns at the different positions in the storage array, and read out the digital calibration codes stored in the storage array according to cycles and transmit the digital calibration codes to the data processing module.

Optionally, the number of the storage array units is N*(N+M). Each of the storage array units includes 7 MOS transistors and 2 RRAMs, wherein 3 MOS transistors serve as signal gating switches, 4 MOS transistors form inverters connected end to end to enhance storage signals, and 2 RRAMs serve as a medium for storing information.

In the calibration mode, the storage array unit is in a write mode, writing the digital calibration codes one by one.

In the operation mode, the storage array unit is in a read mode, reading out the digital calibration codes one by one to the data processing module.

Optionally, the data accumulator of the data processing module is provided to accumulate the received N+M bit digital calibration codes, determine whether an accumulation result exceeds N+M bits, if the accumulation result exceeds the N+M bits, output the N+M bits of “1”, if the accumulation result does not exceed the N+M bits, the data cutter performs a cutting operation on the accumulated data, only retaining the high N bits of the data as output.

Optionally, N=8, M=2.

In a second aspect, the present disclosure also provides a digital foreground calibration method for a successive approximation register analog-to-digital converter based on RRAM, which is executed based on the digital foreground calibration system for the successive approximation register analog-to-digital converter based on RRAM as described in any one embodiment of the first aspect. For a successive approximation register analog-to-digital converter to be calibrated, the calibration mode is performed first, and the subsequent operations are all performed in the operation mode.

When in the calibration mode, the method includes:

The step voltage generating module generating a step voltage Vt for input to the successive approximation register analog-to-digital converter to be calibrated, enabling the successive approximation register analog-to-digital converter to be calibrated to generate different digital output codes;

The status monitoring module detecting the mode of the digital output code, wherein if the mode conforms to a preset output mode, the selector responds to a control signal according to the position of “1” in the digital output code, and injects the control signal into the storage array unit, controlling the storage array unit to perform the write operation on the corresponding digital calibration code.

When in the operation mode, the method includes:

The status monitoring module detecting the mode of the digital output code of the calibrated successive approximation register analog-to-digital converter, and recording the number of “1”s in the digital output code thereof and the position of each “1”, the selector responding to the different control signals according to different digital output codes, and controlling the storage array unit to read out the corresponding digital calibration codes respectively;

The data processing module acquiring the digital calibration codes periodically for data accumulation and cutting, and outputting the calibrated digital output codes.

Through the above technical solutions conceived by the present disclosure, compared with the related art, the following advantageous effects may be achieved:
1. The present disclosure provides the digital foreground calibration system for the successive approximation register analog-to-digital converter based on RRAM. In terms of storage, RRAM is adopted as the medium for storing digital signals, all digital signals are stored in RRAM, making the stored data non-volatile, which will not be lost due to power-on or power-off, thus stability is ensured. As long as the data is written, signal leakage will not occur, making the calibration accuracy increase and the anti-interference capability also enhanced. Therefore, this calibration system only needs to perform one calibration mode for SAR ADC. After obtaining sufficient calibration codes, the ADC may be used without calibration again and may directly enter the operation mode. Thus, the time consumed by calibration is greatly saved, the power consumption required for calibration is significantly reduced, and the speed is improved.
2. The present disclosure provides the digital foreground calibration system for the successive approximation register analog-to-digital converter based on RRAM. In the calibration mode, after the stored N*M-bit digital calibration codes are accumulated and replace the digital output code of the SAR ADC to be calibrated, the dynamic performance of the ADC including an effective number of bits is significantly improved, the unit capacitance value of the ADC is reduced, thereby greatly reducing the energy consumption thereof, improving the energy efficiency of the calibrated ADC, and also reducing the area of the calibrated ADC.
3. The present disclosure provides the digital foreground calibration system for the successive approximation register analog-to-digital converter based on RRAM. The structure mainly includes a multiplexer, an accumulator, and a storage array composed of RRAM. The calibration function may be completed with relatively simple hardware overhead, reducing the area for the entire system and improving the energy efficiency ratio of the system. Among them, RRAM is provided to replace conventional SRAM for data storage. RRAM has the advantages of small area, low power consumption, and high integration, thus may greatly save the area and power consumption required for storage.

### BRIEF DESCRIPTION OF THE DRAWINGS

FIG. 1 is a block diagram of a system structure for the detection, lookup, and reading of calibration codes in a digital foreground calibration system for a successive approximation register analog-to-digital converter based on RRAM, as described in an embodiment of the present disclosure.

FIG. 2 is a block diagram of a system structure for the reading out of calibration codes in a digital foreground calibration system for a successive approximation register analog-to-digital converter based on RRAM, as described in an embodiment of the present disclosure.

FIG. 3 illustrates a calibration principle of a digital foreground calibration system for a successive approximation register analog-to-digital converter based on RRAM, as described in an embodiment of the present disclosure.

FIG. 4 is a flowchart of a calibration algorithm of a digital foreground calibration system for a successive approximation register analog-to-digital converter based on RRAM, as described in an embodiment of the present disclosure.

FIG. 5 is a schematic diagram of an RRAM storage array structure in an embodiment of the present disclosure.

FIG. 6 is a schematic diagram of a specific circuit structure of an RRAM storage unit in an embodiment of the present disclosure.

### DESCRIPTION OF THE EMBODIMENTS

In order to make the purpose, technical solutions and advantages of the present disclosure more clear, the present disclosure is further described in detail below with reference to the accompanying drawings and embodiments. It should be understood that the specific embodiments described herein are only provided to explain the present disclosure and are not provided to limit the present disclosure. In addition, the technical features involved in the various embodiments of the present disclosure described below may be combined with each other as long as they do not conflict with each other.

The content involved in the above embodiments is described below with reference to a preferred embodiment.

### Embodiment 1

The present disclosure provides a digital foreground calibration system for a successive approximation register analog-to-digital converter based on RRAM, including: a step voltage generating module, a status monitoring module, an information storage module and a data processing module. The step voltage generating module is only effective in a calibration mode and is cut off in an operation mode; the data processing module is cut off in the calibration mode and is effective in the operation mode.

The step voltage generating module includes an N+M bit-width counter and a digital-to-analog converter with a resolution of N+M bits. An input terminal of the counter is connected with an external clock, an output terminal of the counter is connected with an input terminal of the digital-to-analog converter, and an output terminal of the digital-to-analog converter is connected with an input terminal of the successive approximation register analog-to-digital converter to be calibrated. The counter is provided to generate a continuously self-incrementing digital code, and the digital-to-analog converter is provided to convert a digital code into a continuously rising analog step voltage Vt for output to the successive approximation register analog-to-digital converter to be calibrated, wherein, M and N are both positive integers.

The status monitoring module includes a status detection logic unit and a selector. In the calibration mode, an input terminal of the status detection logic unit is connected with an output terminal of the successive approximation register analog-to-digital converter to be calibrated, an output terminal of the status detection logic unit is connected with an input terminal of the selector, and an output terminal of the selector is connected with the information storage module. The status detection logic unit is provided to detect a mode of a digital output code of the successive approximation register analog-to-digital converter to be calibrated, and the selector is provided to respond to different control signals according to the mode of the digital output code. In the operation mode, an input terminal of the status monitoring logic unit is connected with the output terminal of the calibrated successive approximation register analog-to-digital converter. The status detection logic unit is provided to detect the mode of the digital output code of the calibrated successive approximation register analog-to-digital converter, and the selector is provided to respond to the different control signals according to the mode of the digital output code.

The information storage module includes an address control unit and an RRAM-based storage array unit. In the calibration mode, the storage array unit is connected with the counter, and is provided to store N (N+M)-bit digital calibration codes generated by the step voltage generating module. The address control unit is provided to select different columns in a storage array according to the control signal output by the status monitoring module, and write the digital calibration codes into the storage array. In the operation mode, the storage array unit is connected with the data processing module, and the address control unit is provided to select the different columns in the storage array according to the control signal output by the status monitoring module, and read the digital calibration codes from the storage array.

The data processing module includes an N+M-bit data accumulator and an N-bit data cutter. An input terminal of the data accumulator is connected with the information storage module, and an output terminal of the data accumulator is connected with an input terminal of the data cutter. The data accumulator is provided to accumulate the selected N+M-bit digital calibration codes in the information storage module, and the data cutter is provided to cut the data, only retaining the top N bits, serving as an output of the calibrated successive approximation register analog-to-digital converter.

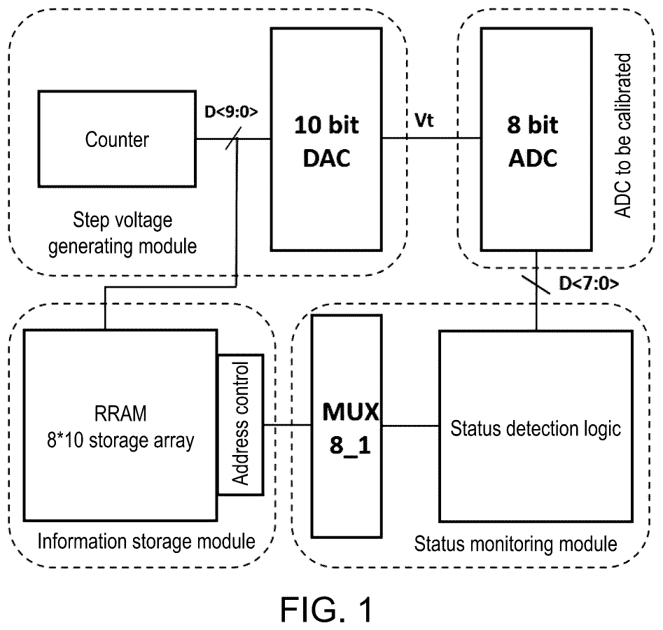

The disclosure provides the digital foreground calibration method based on RRAM, which is conducted in two parts during actual operation. Initially, the system enters the calibration mode. Once calibration is complete, the system is switched to the operation mode when the calibrated ADC is in operation, during which the calibration codes calculated and stored in the calibration mode are read out to calibrate output codes of the ADC. The block diagram of the hardware system structure for the calibration mode of this digital foreground calibration method based on RRAM is illustrated in FIG. 1. The hardware system corresponding to the calibration mode primarily includes four modules: the step voltage generating module, the ADC module to be calibrated, the status monitoring module, and the information storage module.

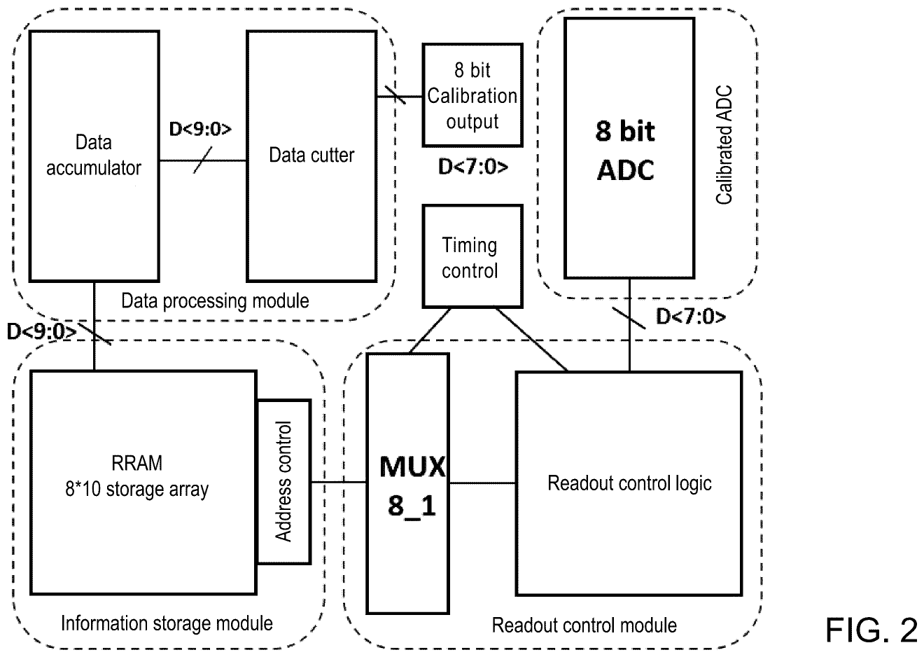

After the calibration mode is completed, the calibrated SAR ADC completes calibration and starts to enter the operation mode. The hardware system corresponding to the operation mode is mainly composed of four modules, which are the ADC module to be calibrated, the status monitoring module, the information storage module, and the data processing module. The system block diagram of the data readout and processing part of this RRAM-based digital foreground calibration scheme in the SAR ADC operation mode is shown in FIG. 2.

In the calibration mode, an analog step voltage Vt generated by the step voltage generating module is stored and input into the successive approximation register analog-to-digital converter to be calibrated. After the analog step voltage Vt passes through the analog-to-digital converter, the digital output code is generated. The status detection module receives the digital output code of the ADC to be calibrated and detects the mode thereof, selectively storing the digital output code into the corresponding position in the storage array as the digital calibration code. The RRAM storage array is composed of storage units with a 7T2R structure. In operation mode, the information storage module continuously input data into the data processing module for accumulation and cutting to generate the calibrated output code.

With the above structure, the effective precision and conversion linearity of the calibrated SAR ADC may be improved, and the requirements of the calibrated SAR ADC for the size and area of the unit capacitance in the DAC may be reduced. The power consumption of digital-to-analog conversion is reduced through the foreground calibration method, and memristors with non-volatility are introduced for storage, which improves the data stability and reduces the calibration cycle.

Optionally, the counter receives an external clock signal, and at each rising edge of a clock, the output is self-incremented to generate a digital code with a bit-width of N+M bits.

The digital-to-analog converter periodically converts the digital output code of the counter into an analog voltage under the control of a system clock, obtaining the step voltage Vt, and output the step voltage Vt to the successive approximation register analog-to-digital converter. The step voltage Vt includes all scenarios of an N-bit digital output.

Optionally, in the calibration mode, the status monitoring module is provided to automatically detect the mode of the digital output code of the successive approximation register analog-to-digital converter to be calibrated, detecting whether its mode is only one bit being “1” while all remaining bits are “0”. If a detection result is true, then a position where “1” is located in the digital output code is detected, and the selector is provided to respond to the different control signals according to the detected position and output to the information storage module. If the detection result is false, then a current calibration cycle is directly skipped.

In the operation mode, the status monitoring module is provided to automatically monitor the mode of the digital output code of the calibrated successive approximation register analog-to-digital converter, detecting the number n of digital codes being “1” therein, and accordingly setting an operation cycle of this operation mode to n, and detecting a position where each “1” is located in the digital output code. The selector is provided to respond to the different control signals for each different “1” in the following n operation cycles.

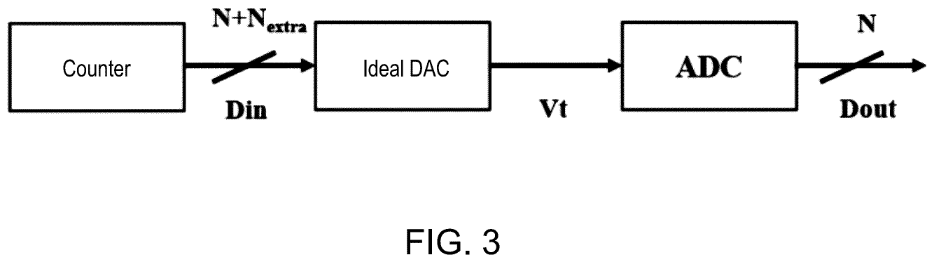

An embodiment of the present disclosure is specifically described in conjunction with the accompanying diagram, as illustrated in FIG. 3, which is a schematic diagram of the calibration principle for the digital foreground calibration scheme for SAR ADC based on RRAM. A counter generates a continuously self-incrementing digital input signal Din, a bit length of the digital signal is N+Nₑₓₜᵣₐ bits, where N represents a resolution N of the SAR ADC being calibrated, and Nₑₓₜᵣₐ denotes a difference between the bit length of the digital signal output by the counter and a bit length of the ADC. The continuously self-incrementing digital input signal Din drives an ideal DAC, causing the DAC to produce an ideally continuous ascending step signal Vt. This step signal Vt is input into the SAR ADC being calibrated, and is sampled by the ADC. After N conversion cycles, the calibrated SAR ADC outputs an N-bit digital signal Dout.

When an output result Dout is 00 . . . 001, meaning only the LSB is ‘1’ and all other bits are ‘0’, the corresponding Din will be stored in a register implemented by RRAM. After the completion of the subsequent calibration mode, the SAR ADC enters the operation mode. In this operation mode of the SAR ADC, when the LSB code is ‘1’, the stored Din will be invoked to replace the currently output Dout. Subsequently, the step signal Vt continues to rise and is input into the calibrated ADC. When the output result Dout of the ADC is 00 . . . 010, the aforementioned process is repeated, the corresponding Din is stored into the respective RRAM register. The Vt signal then continues to increase until all bits of Dout have corresponding registers storing the calibration code Din, at which point the calibration mode concludes.

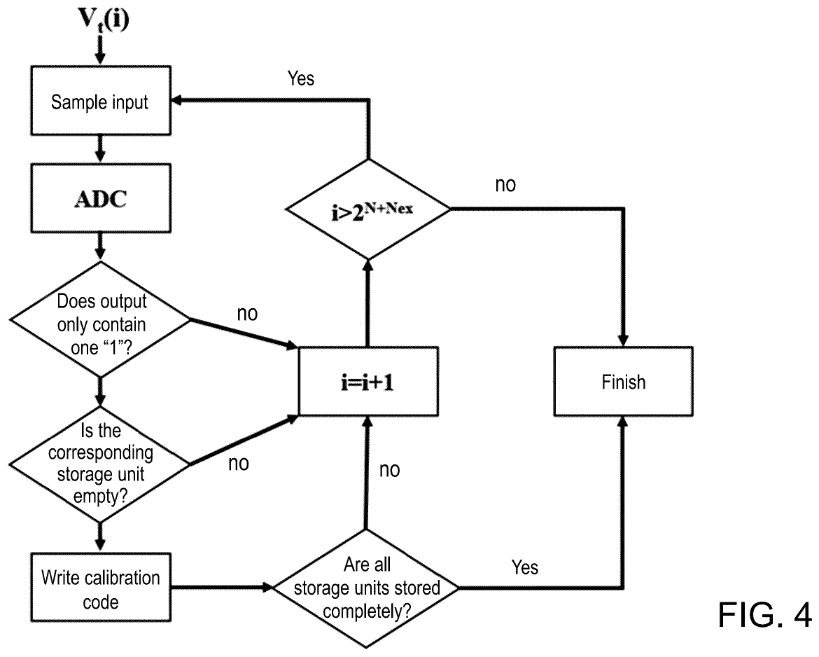

As illustrated in FIG. 4, which is a flowchart of a calibration algorithm of the digital foreground calibration system for the SAR ADC based on RRAM, an ideal step signal Vt(i), generated by the counter and ideal DAC, is sampled as input by the SAR ADC. After N conversion cycles, the ADC outputs an N-bit digital signal Dout. An output pattern detection module then checks whether Dout contains only a single ‘1’ with all other bits being ‘0’. If the detection result is affirmative, the detection module further checks whether the register corresponding to the position of the ‘1’ is empty. If the corresponding register is empty, the corresponding Din, i.e., the calibration code for that bit, is written into the RRAM-based register. If the corresponding register is not empty, the current cycle ends, a value i output by the counter is incremented by 1, and the step signal Vt rises to continue inputting to the SAR ADC for the next cycle. If the detection result indicates that Dout does not contain only a single ‘1’, the current cycle is prematurely terminated, and the process proceeds directly to the next cycle as described above.

The conclusion of the calibration mode is subject to two adjudicative conditions, either of which, when satisfied, shall be deemed as the completion of the calibration process. These two conditions are as follows: whenever an operation to write to the RRAM registers is concluded, the status of all registers shall be examined. If it is determined that all RRAM registers have been fully written, the calibration shall be considered complete. Alternatively, upon each self-increment of the output i of the counter, if it is determined that the value of i is not less than 2^{N+Nextra}, if the result is negative, then the condition shall also be deemed as the completion of the calibration.

Optionally, in the calibration mode, the address control unit within the information storage module is employed to receive control signals in response to the status detection module. The columns at the different positions within the storage array are selected, and the digital output codes corresponding to that cycle are stored in the respective positions as the digital calibration codes.

In the operational mode, the address control unit within the information storage module is utilized to receive control signals in response to the status detection module. The columns at the different positions within the storage array are selected, and the digital calibration codes stored in the storage array are read out periodically and transmitted to the data processing module.

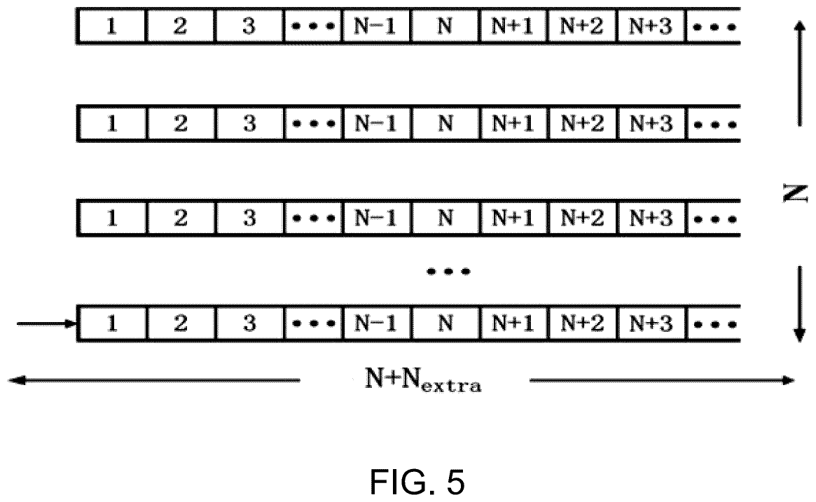

As illustrated in FIG. 5, FIG. 5 is a schematic diagram of an RRAM storage array structure. The information storage module is primarily composed of two parts: an 8*10 storage array based on RRAM and an address control logic module. The address control logic mainly consists of a counter, an address pointer, and some minor control logic.

In this embodiment, N is set to 8 and M to 2. The capacity of the RRAM storage array in this embodiment is 8*10, where 8 represents the resolution N of the SAR ADC being calibrated in this embodiment, and 10 represents the bit width N+Nₑₓₜᵣₐ of the output from the counter in this embodiment. This RRAM storage array consists of 8 RRAM registers, each register has a width of 10 bits. Each bit of data is stored in a storage unit composed of a 7T2R structure based on RRAM. Additionally, the RRAM storage array further includes a pointer controlled by pattern detection logic. Once a pattern detection module detects that the output Dout of the SAR ADC meets the pattern detection condition at a specific moment, the position of ‘1’ in Dout is identified and the address of that position is sent to the pointer in the RRAM storage array. This enables the pointer to reference the corresponding 10-bit register in the RRAM storage array, thereby storing the corresponding 10-bit calibration code Din into the register corresponding to the RRAM storage array. When the input signal Vt sweeps from 0 to the MSB position of the SAR ADC being calibrated, and the pointer finally points to the register corresponding to the MSB in the RRAM storage array, upon completion of the writing operation, the calibration may be considered complete. This saves subsequent non-essential calibration cycles and shortens the time required for the calibration mode. Compared to sweeping Vt across the full range, this method may save 50% of the calibration cycles.

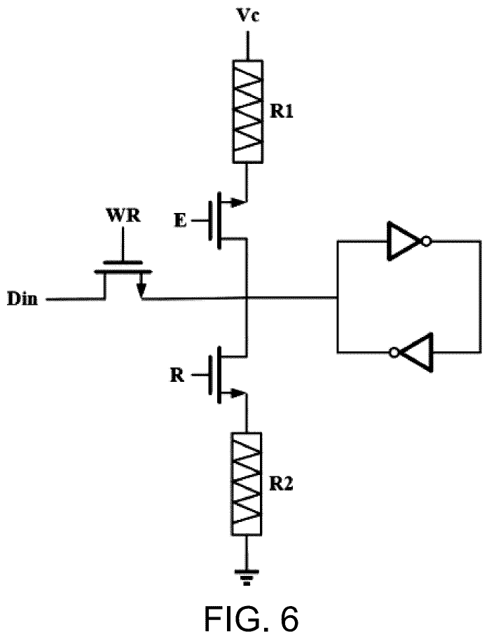

In the above description, each of the storage units in the 8*10 RRAM storage array is not composed of conventional SRAM or DRAM, but is instead constituted by a 7T2R structure based on RRAM, the principle diagram of said structure is illustrated in FIG. 6.

Optionally, the number of storage array units is N*(N+M). Each of the storage array units includes seven MOS transistors and two RRAMs, among which three MOS transistors function as gating switches for signals, four MOS transistors form an inverter connected end to end to enhance the storage signal, and the two RRAMs serve as the medium for storing information.

In the calibration mode, the storage array unit is in a write mode, writing the digital calibration codes one by one.

In the operation mode, the storage array unit is in a read mode, reading out the digital calibration codes one by one to the data processing module.

Specifically, the storage array unit is composed of three control switch transistors, two RRAM units responsible for information storage, and two inverters connected end to end, each constructed with four transistors. An input terminal of this storage unit is the drain of the switch transistor, designated as Din, and an output terminal of this storage unit is the source of the switch transistor, designated as Dout. A gate of this switch transistor is controlled by a WR signal, while the gates of the other two switch transistors are controlled by an E signal and an R signal, respectively. Here, WR represents the read/write operation, E signifies enable, and R denotes the read operation. The source of the switch transistor controlled by the E signal is connected to a memristor R1, with the other end of the memristor R1 connected to a voltage Vc, which is provided to store the written 1-bit information. The source of the switch transistor controlled by the R signal is connected to a memristor R2, with the other end of the memristor R2 connected to the ground, which is provided to read out the 1-bit information stored by the memristor R1.

Furthermore, the operational principle of the RRAM-based 7T2R unit is as follows:

During a reset phase, all control signals, namely the WR signal, E signal, and R signal, are at a low level, thereby turning off the three controlled switch transistors. The memristors R1 and R2 are both initially in a high-resistance status. When a 1-bit signal Din requests writing, the WR signal transitions from a low level to a high level, indicating that the signal is valid, and simultaneously opens the controlled switch transistors, allowing Din to pass directly to the next node. At this time, the E signal also transitions from a low level to a high level, indicating that the signal is valid, and the controlled switch transistors are opened simultaneously. However, the R signal remains at a low level, meaning the switch transistor controlled by the R signal remains off. At this point, Din will only be transmitted to a lower plate of the memristor R1, which writes and stores the information by lowering its resistance status or keeping the resistance status unchanged. When Din is 1, the memristor R1 transitions from a high-resistance status to a low-resistance status, representing the storage of “1”. When Din is 0, the memristor R1 maintains its initial high-resistance status, representing the storage of “0”. In the subsequent clock cycle, the WR and E signals are reset to a low level, turning off the switch transistors, thus completing the writing of information. The information is stored in the form of different resistance statuses of the memristor R1.

When the stored 1-bit signal is requested to be read, the WR signal remains at a low level, maintaining its status. The controlled switch transistor is turned off, isolating the input from the output. Subsequently, both the E signal and the R signal transition simultaneously from a low level to a high level, indicating the validity of the signal, and activating the two controlled switch transistors. At this point, a short pulse signal is input at a Vc terminal. Since both the E signal and R signal are valid, the memristors R1 and R2 may be considered as conducting. The stored information may be read out through a voltage division of the resistances of the two memristors. If the stored information is “1,” the memristor R1 is in a low resistance status, and the memristor R2 is in a high resistance status. After the voltage division through the memristors, the output terminal outputs Vc. Therefore, by controlling the value of Vc to be greater than half of VDD, the subsequent inverter may pull the output to “1.” If the stored information is “0,” the memristor R1 is in a high resistance status, and the memristor R2 is also in a high resistance status. After the voltage division through the memristors, the output terminal outputs approximately Vc/2. By controlling Vc/2 to be less than half of VDD, the subsequent inverter may pull the output to “0.” Therefore, the high level of the short pulse, Vc, should be controlled to be less than VDD but greater than VDD/2. For example, setting the value to 3/4 VDD ensures that the signal may be correctly read out, with sufficient noise margins at both the upper and lower ends, enhancing the accuracy and stability of the signal readout. The two inverters connected end to end are responsible for maintaining the signal during both read and write operations, especially enhancing the signal driving capability during read operations.

Optionally, the data accumulator of the data processing module is provided to accumulate the received N+M bit digital calibration codes, determine whether an accumulation result exceeds N+M bits, if the accumulation result exceeds the N+M bits, output the N+M bits of “1”, if the accumulation result does not exceed the N+M bits, the data cutter performs a cutting operation on the accumulated data, only retaining the high N bits of the data as output.

In an embodiment of the present disclosure, in terms of storage, RRAM is utilized as the medium for storing digital signals. All digital signals are stored in RRAM, granting the stored data non-volatility and ensuring that the data is not lost due to power cycling. This calibration system requires only a single calibration mode for the SAR ADC. After obtaining sufficient calibration codes, the ADC may subsequently be used without further calibration, allowing the ADC to directly enter the operation mode. By reducing the unit capacitance area of the SAR ADC, the power consumption thereof is decreased. The use of RRAM for storage, which is non-volatile, makes it suitable for in-memory computing applications. This resolves the technical issue in existing digital foreground calibration schemes that lack non-volatility, causing stored data to be lost after each power-down and necessitating entry into calibration mode before each operation, thereby wasting considerable time and energy. The disclosure enhances calibration stability and interference resistance, reduces the area, and lowers power consumption. The present disclosure saves the time and power required for calibration, thereby increasing speed.

### Embodiment 2

The present disclosure also provides a digital foreground calibration method for a successive approximation register analog-to-digital converter based on RRAM, which is executed based on the digital foreground calibration system for the successive approximation register analog-to-digital converter based on RRAM as described in any embodiment of Embodiment 1. For the successive approximation register analog-to-digital converter to be calibrated, a calibration mode is performed first, and subsequently all are operation modes.

When in the calibration mode, the method includes:

The step voltage generating module generating the step voltage Vt to input to the successive approximation register analog-to-digital converter to be calibrated, causing the successive approximation register analog-to-digital converter to generate different digital output codes;

The status monitoring module detecting the mode of the digital output code, wherein if the mode conforms to a preset output mode, the selector responds to a control signal according to the position of “1” in the digital output code, and injects the control signal into the storage array unit, controlling the storage array unit to perform the write operation on the corresponding digital calibration code.

When in the operation mode, the method includes:

The status monitoring module detecting the mode of the digital output code of the calibrated successive approximation register analog-to-digital converter, and recording the number of “1”s in the digital output code thereof and the position of each “1”, the selector responding to the different control signals according to different digital output codes, and controlling the storage array unit to read out the corresponding digital calibration codes respectively;

The data processing module acquiring the digital calibration codes periodically for data accumulation and cutting, and outputting the calibrated digital output codes.

In a specific embodiment, when the calibration mode is initiated, the system waits for a rising edge of a start clock, at which point the counter begins to operate, outputting a continuously self-incrementing 10-bit digital code. This digital code is 2 bits redundant compared to the 8-bit SAR ADC to be calibrated in this embodiment. This 2-bit precision redundancy is considered appropriate because these calibration codes are accumulated during the operation mode to replace the output code of the SAR ADC for calibration purposes. This approach enhances calibration precision without introducing an excessive number of RRAM storage units and also reduces the complexity of the associated logic circuits, thereby conserving power consumption and minimizing hardware costs.

The continuously self-incrementing 10-bit digital code is input into a 10-bit DAC, whereby the self-incrementing digital code is converted into an ideal step analog voltage, denoted as Vt. The precision of Vt, or the step size of the step voltage, corresponds to one Least Significant Bit (LSB) value of the 10-bit DAC. Given that the resolution or precision of the preceding DAC exceeds that of the subsequent 8-bit SAR ADC to be calibrated, the step size of the step voltage is sufficiently small to encompass all equivalent input signals of the subsequent SAR ADC. Consequently, when the 10-bit precision step signal Vt is input into the 8-bit SAR ADC for calibration, the output code values of this ADC are guaranteed to ascend gradually from the minimum value of 0. . . 00 to the maximum value of 1 . . . 11. This ensures the potential coverage of all possible output code values of the 8-bit SAR ADC. Thus, within these ADC output codes, there will inevitably be all output codes that satisfy the status detection conditions, ensuring the absence of any missing codes.

When the output code of the 8-bit SAR ADC with the aforementioned characteristics is input into the status monitoring module, the module automatically detects ADC output codes that meet the specified conditions and simultaneously executes subsequent operations. This module consists of two parts: the status detection logic and an 8-to-1 data selector. According to the calibration algorithm, the status detection logic identifies ADC output codes characterized by a single “1” bit with all other bits being “0”. If the detection logic finds an ADC output code that satisfies all requirements or specifications of the algorithm, such as 0 . . . 010, the detection logic regards this output code as a valid signal. Different 3-bit selection signals are generated based on the position of the “1” in the output code to control the subsequent 8-to-1 selector. Assuming the position of the “1” is the n-th bit of the output code, the detection logic generates a 3-bit selection signal representing n-1. For instance, in this example, if the value “1” is at the second bit of the ADC output code, the detection logic will generate a 3-bit selection signal sel, representing “1”, i.e., 001, to control the subsequent logic circuit. If the detected ADC output code is 010 . . . 0, the detection logic will generate a selection signal sel<2:0> representing “6”, i.e., 110. This selection signal sel<2:0>, after passing through the 8-to-1 selector, will then activate a uniquely valid address channel corresponding to the different positions of the “1” in the ADC output code.

In the information storage module, an address pointer initially points to the first column of the 10-bit RRAM-based storage unit. This column storage unit corresponds to the LSB of the 8-bit SAR ADC pending calibration. Upon receiving the channel selection signal transmitted by the 8-to-1 selector, the address pointer selects a specific column of the RRAM register, then stores the 10-bit calibration code corresponding to that cycle into the corresponding RRAM column storage unit, which is, at this time, pointed to by the address pointer. Once the 8-column 10-bit calibration codes have been fully stored within the 8*10 RRAM array, and the address pointer points to the highest column of the RRAM register with non-empty status, a finish signal is generated to indicate the end of the calibration mode, signifying that calibration is complete. The RRAM storage array now contains 8 columns of 10-bit calibration codes, which correspond sequentially from low to high to the calibration codes when the ADC output mode pending calibration is from 0 . . . 01 to 10 . . . 0, respectively.

Upon completion of the calibration mode, the calibrated SAR ADC finalizes its calibration and transitions into the operation mode. The system block diagram for data readout and processing within the SAR ADC operation mode, utilizing the RRAM-based digital foreground calibration scheme, is depicted in FIG. 2. Once the calibrated 8-bit SAR ADC completes a data conversion, an 8-bit digital output code is produced, referred to herein as the pre-calibration output code. The readout control logic within a readout control module is responsible for acquiring the pre-calibration output code from the SAR ADC. Initially, the number of bits set to “1” in the pre-calibration output code is detected, and their sum using a detection and accumulation logic is calculated. If there are n “1” bits, the operation cycle for the entire digital foreground calibration module is set to n. In each cycle, the position of each “1” bit is examined subsequently, with the readout control logic managing the subsequent MUX 8-to-1 selector to generate distinct outputs, thereby selecting different stored calibration codes. For instance, if a specific conversion cycle of the calibrated 8-bit SAR ADC yields a pre-calibration output code of 1001_0010, the readout control logic sequentially accumulates the number of “1” bits in the pre-calibration output code, which in this case totals to 3. Consequently, a timing control module sets the operation cycle of the digital foreground calibration module to 3. In the first operation cycle, the lowest positional “1” is detected, which in this scenario is the second bit. Therefore, the readout control logic transmits the information “2” through the subsequent 8-to-1 selector to the subsequent information storage module, selecting the 10-bit calibration code stored in the RRAM-based register corresponding to the second column via an address control module. Similarly, in the second operation cycle, the next lowest positional “1” is identified, which is the fifth bit in this example. The readout control logic then conveys the information “5” through the subsequent 8-to-1 selector to the subsequent information storage module, selecting the 10-bit calibration code stored in the RRAM-based register pertaining to the fifth column via the address control module. Finally, in the third operation cycle, the highest positional “1” is detected, which is the eighth bit in this example. The readout control logic thus transmits the information “8” through the subsequent 8-to-1 selector to the subsequent information storage module, selecting the 10-bit calibration code stored in the RRAM-based register corresponding to the eighth column via the address control module.

Upon completion of the detection of the number of “1”s in the output code prior to calibration and the extraction of the information regarding the position of each “1” by the readout control module, the 8*10 RRAM storage array within the information storage module, under the control of the address control module, sequentially outputs the corresponding 10-bit digital calibration code to the data accumulator in the subsequent data processing module. Each operation cycle extracts one column corresponding to a 10-bit calibration code for a “1” located in the output code prior to calibration. When the final operation cycle specified by the timing control module is reached, an EN enable signal is sent to the data processing module, prompting the module to commence processing all received data. Initially, the data accumulator continuously performs an accumulation operation on the n 10-bit calibration codes from the 8*10 RRAM storage array, where n is determined by the number of “1”s detected in the uncalibrated output code of the SAR ADC by the readout control module. Upon completion of the accumulation, since the result is a 10-bit digital code and an 8-bit calibrated output code is required, the 10-bit accumulated digital code is input into the data cutter to perform data cutting operation, retaining only the high eight bits. The final output is the 8-bit calibrated output, thus completing one cycle of digital foreground calibration in the SAR ADC operation mode.

The execution of the digital foreground calibration method for the successive approximation register analog-to-digital converter based on RRAM, as provided by embodiments of the present disclosure, is dependent on the digital foreground calibration system for the successive approximation register analog-to-digital converter based on RRAM, provided by any embodiment of the present disclosure, and exhibits corresponding advantageous effects.

It will be readily understood by those skilled in the art that the foregoing description is merely a preferred embodiment of the present disclosure and is not intended to limit the disclosure. Any modifications, equivalent substitutions, or improvements made within the spirit and principles of the present disclosure shall be included within the scope to be protected by this disclosure.

What is claimed is:

1. A digital foreground calibration system for a successive approximation register analog-to-digital converter based on RRAM, comprising: a step voltage generating module, a status monitoring module, an information storage module and a data processing module, wherein the step voltage generating module is only effective in a calibration mode and is cut off in an operation mode, the data processing module is cut off in the calibration mode and is effective in the operation mode;
the step voltage generating module comprises an N+M bit-width counter and a digital-to-analog converter with a resolution of N+M bits, an input terminal of the counter is connected with an external clock, an output terminal is connected with an input terminal of the digital-to-analog converter, and an output terminal of the digital-to-analog converter is connected with an input terminal of the successive approximation register analog-to-digital converter to be calibrated, the counter is provided to generate a continuously self-incrementing digital code, and the digital-to-analog converter is provided to convert the digital code into a continuously rising analog step voltage Vt for output to the successive approximation register analog-to-digital converter to be calibrated, wherein, M and N are both positive integers;
the status monitoring module comprises a status detection logic unit and a selector, in the calibration mode, an input terminal of the status detection logic unit is connected with an output terminal of the successive approximation register analog-to-digital converter to be calibrated, an output terminal is connected with an input terminal of the selector, and an output terminal of the selector is connected with the information storage module, the status detection logic unit is provided to detect a mode of a digital output code of the successive approximation register analog-to-digital converter to be calibrated, and the selector is provided to respond to different control signals according to the mode of the digital output code; in the operation mode, an input terminal of the status monitoring logic unit is connected with the output terminal of the calibrated successive approximation register analog-to-digital converter, the status detection logic unit is provided to detect the mode of the digital output code of the calibrated successive approximation register analog-to-digital converter, and the selector is provided to respond to the different control signals according to the mode of the digital output code;
the information storage module comprises an address control unit and an RRAM-based storage array unit, in the calibration mode, the storage array unit is connected with the counter, and is provided to store N (N+M)-bit digital calibration codes generated by the step voltage generating module, the address control unit is provided to select different columns in a storage array according to the control signal output by the status monitoring module, and write the digital calibration codes into the storage array; in the operation mode, the storage array unit is connected with the data processing module, and the address control unit is provided to select the different columns in the storage array according to the control signal output by the status monitoring module, and read the digital calibration codes from the storage array;
the data processing module comprises an N+M-bit data accumulator and an N-bit data cutter, an input terminal of the data accumulator is connected with the information storage module, and an output terminal is connected with an input terminal of the data cutter, the data accumulator is provided to accumulate the selected N+M-bit digital calibration codes in the information storage module, and the data cutter is provided to cut data, only retaining the top N bits, serving as an output of the calibrated successive approximation register analog-to-digital converter.

2. The digital foreground calibration system according to claim 1, wherein the counter receives an external clock signal, and at each rising edge of the clock signal, an output is self-incremented to generate a digital code with a bit-width of N+M bits;
the digital-to-analog converter periodically converts the digital output code of the counter into an analog voltage under the control of a system clock, obtaining the step voltage Vt, and output the step voltage Vt to the successive approximation register analog-to-digital converter, the step voltage Vt comprises all scenarios of an N-bit digital output.

3. The digital foreground calibration system according to claim 2, wherein in the calibration mode, the status monitoring module is provided to automatically detect the mode of the digital output code of the successive approximation register analog-to-digital converter to be calibrated, detecting whether its mode is only one bit being “1” while all remaining bits are “0”, if a detection result is true, then a position where “1” is located in the digital output code is detected, and the selector is provided to respond to the different control signals according to the detected position and output to the information storage module, if the detection result is false, then a current calibration cycle is directly skipped;
in the operation mode, the status monitoring module is provided to automatically monitor the mode of the digital output code of the calibrated successive approximation register analog-to-digital converter, detecting the number n of digital codes being “1” therein, and accordingly setting an operation cycle of the operation mode to n, and detecting the position where each “1” is located in the digital output code, the selector is provided to respond to the different control signals for each different “1” in the following n operation cycles.

4. The digital foreground calibration system according to claim 2, wherein in the calibration mode, the address control unit in the information storage module is provided to receive the control signal responded by the status detection module, select the columns at different positions in the storage array, and store the digital output code corresponding to a cycle to a corresponding position as the digital calibration code;
in the operation mode, the address control unit in the information storage module is provided to receive the control signal responded by the status detection module, select the columns at the different positions in the storage array, and read out the digital calibration codes stored in the storage array according to cycles and transmit the digital calibration codes to the data processing module.

5. The digital foreground calibration system according to claim 4, wherein a number of the storage array units is N*(N+M), each of the storage array units comprises 7 MOS transistors and 2 RRAMs, wherein 3 MOS transistors serve as signal gating switches, 4 MOS transistors form inverters connected end to end to enhance storage signals, and 2 RRAMs serve as a medium for storing information;
in the calibration mode, the storage array unit is in a write mode, writing the digital calibration codes one by one;
in the operation mode, the storage array unit is in a read mode, reading out the digital calibration codes one by one to the data processing module.

6. The digital foreground calibration system according to claim 1, wherein the data accumulator of the data processing module is provided to accumulate the received N+M bit digital calibration codes, determine whether an accumulation result exceeds N+M bits, if exceeds, output the N+M bits of “1”, if not exceed, the data cutter performs a cutting operation on the accumulated data, only retaining the high N bits of the data as output.

7. The digital foreground calibration system according to claim 1, wherein N=8, M=2.

8. A digital foreground calibration method for a successive approximation register analog-to-digital converter based on RRAM, executed based on the digital foreground calibration system for the successive approximation register analog-to-digital converter based on RRAM according to claim 1, wherein, for the successive approximation register analog-to-digital converter to be calibrated, the calibration mode is performed first, and subsequent operations are all performed in the operation mode;
when in the calibration mode, the digital foreground calibration method comprising:
the step voltage generating module generating the step voltage Vt for input to the successive approximation register analog-to-digital converter to be calibrated, enabling the successive approximation register analog-to-digital converter to be calibrated to generate the different digital output codes;
the status monitoring module detecting the mode of the digital output code, wherein if the mode conforms to a preset output mode, the selector responds to the control signal according to a position of “1” in the digital output code, and injects the control signal into the storage array unit, controlling the storage array unit to perform a write operation on the corresponding digital calibration code;
when in the operation mode, the digital foreground calibration method comprising:
the status monitoring module detecting the mode of the digital output code of the calibrated successive approximation register analog-to-digital converter, and recording a number of “1”s in the digital output code thereof and the position of each “1”, the selector responding to the different control signals according to the different digital output codes, and controlling the storage array unit to read out the corresponding digital calibration codes respectively; and
the data processing module acquiring the digital calibration codes periodically to perform data accumulation and cutting, and outputting the calibrated digital output codes.
